(19) United States
(12) Patent Application Publication
(10) Pub. No.: US 2005/0062088 A1
(43) Pub. Date: Mar. 24, 2005

(54) Multi-gate one-transistor dynamic random access memory

(75) Inventor: Theodore W. Houston, Richardson, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 10/667,615

(22) Filed: Sep. 22, 2003

(51) Int. Cl. H01L 27/108

(52) U.S. Cl. 257/296; 438/238

(57) ABSTRACT

The present invention provides a one-transistor dynamic random access memory (1T DRAM) device (100). The 1T DRAM device (100) includes a body region (105) insulated (110) from a substrate (115) and an insulating layer (120) on a surface of the body region (125). A gate structure (130) is on the insulating layer (120) and conformally surrounding portions of the body region (105). A width of the body region (145) is sufficient to provide a not fully depleted region. Other embodiments include a method of manufacturing a 1T DRAM device (200) and an integrated circuit (300).

### TECHNICAL FIELD OF THE INVENTION

The present invention is directed, in general, to memory devices and, more specifically, to a multi-gate one-transistor dynamic random access memory (1T DRAM) device.

### BACKGROUND OF THE INVENTION

Virtually all microprocessor and digital signal processor applications would benefit from integrated circuits having an increased packing density of memory. A 1T DRAM advantageously eliminates the need for a separate capacitive element associated with a transistor in a conventional DRAM device. To store memory in a 1T DRAM (e.g., logic state “1”), a charge is transiently stored in the body region of a not fully depleted substrate by applying a voltage pulse to the drain. The charge in the body region can be removed (e.g., logic state “0”) by applying an opposite voltage to the drain. The state of charge in the body region changes the threshold voltage (V_{T}) of the 1T DRAM, which in turn, changes the current passing through the channel of the 1T DRAM. The memory state of the 1T DRAM can thus be read by measuring the drain current for a given gate voltage.

As the dimensions of transistor devices continue to be decreased, however, it is increasingly difficult to deal with short channel effects, increased on-currents and threshold voltage control. In planar-gate transistor devices, for instance, in addition to the gate controlling the channel, fringe fields from the source, drain or substrate also affect the channel. These fringe fields lower the threshold voltage and cause drain induced barrier lowering, which in turn, increases the leakage current of the transistor. In addition, coupling between the source and body degrades the subthreshold current such that the ratio Iₒₙ:I_{off} is lowered.

Multi-gate transistor structures provide improved control of the channel, and thus superior Ion:Ioff, relative to planar single gate transistor structures. Double gate is one form of multi-gate in which there are two gates, one on each of two opposing sides of the body. With double gate, the thickness of the semiconductor between the two gates is preferably equal or less than ⅔ of the gate length. Also, the body is fully depleted so that both gates influence conduction in all parts of the body. FinFET is one form of double gate. Tri-gate is another form of multi-gate. In tri-gate, there are three gates, each on a separate side of the body, two opposing and one adjacent to the two opposing.

With tri-gate, the thickness of the semiconductor between the two opposing gates is preferably equal to or less than the gate length. For conventional FinFET and tri-gate transistors, the width of semiconductor between the opposing gate sides is referred to as the body width, and the thickness of the body region in the direction perpendicular to the length and the width is refered to as the body height. For ease of fabrication and uniformity of optimized transistor characteristics, all conventional FinFET and tri-gate transistors in an integrated circuit are made with substantially the same body width and body height. To get the effect of different drive current transistors, multiple transistors of substantially identical body width and height are connected in parallel. Thus the body of each transistor is optimally fully depleted and the channel is well-controlled by the multiple gates. However, with multi-gate transistors that optimally have fully depleted body regions, sufficient storage of charge in the body for the 1T memory is problematic.

Therefore what is needed in the art is a multi-gate transistor design, suitable for use as a 1T DRAM device and method of manufacturing the same.

### SUMMARY OF THE INVENTION

To address the above-discussed deficiencies of the prior art, the present invention provides a one-transistor dynamic random access memory (1T DRAM) device. The 1T DRAM device includes a body region insulated from a substrate and an insulating layer on a surface of the body region. A gate structure on the insulating layer and conformally surrounding a portion of the body region. A width of the body region is sufficient to provide a not fully depleted region.

The present invention is also directed to a method of manufacturing a 1T DRAM device. The method includes forming a body region insulated from a substrate and depositing an insulating layer on a surface of the body region. The method further includes forming a gate structure on the insulating layer and conformally surrounding a portion of the body region, wherein a width of the body region is sufficient to provide a not fully depleted region.

Another embodiment is an integrated circuit. The integrated circuit includes a 1T DRAM device as described above, and a logic transistor located on the substrate. The integrated circuits further includes interconnects to interconnect the 1T DRAM and the logic transistor to form an operative integrated circuit.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the scope of the invention.

### BRIEF DESCRIPTION OF THE DRAWINGS

For a more complete understanding of the present invention, reference is now made to the following detailed description taken in conjunction with the accompanying FIGUREs. It is emphasized that various features may not be drawn to scale. In fact, the dimensions of various features may be arbitrarily increased or reduced for clarity of discussion. Reference is now made to the following descriptions taken in conjunction with the accompanying drawings, in which:

FIG. 1 illustrates a perspective view of one embodiment of a 1T DRAM device of the present invention;

FIGS. 2A to 2H illustrate sectional views of selected steps in a method of manufacturing a 1T DRAM device according to the principles of the present invention; and

FIG. 3 illustrates a sectional view of selected portions of an exemplary integrated circuit of the present invention.

### DETAILED DESCRIPTION

The present invention recognizes the advantageous use of a multi-gate structure to form a 1T DRAM device. For circuit speed, short gate lengths are desired. Multi-gate transistors offer better control in the channel of the body region, thereby mitigating the above-mentioned deleterious effects of short gate lengths. For instance, multi-gate logic transistors having gate lengths of less about 50 nanometers is highly desirable. It is well known that conventional multi-gate transistors are designed such that the gate workfunction causes the body region to be fully depleted of charge carriers. A fully depleted body region is necessary to get the full benefit of the multi-gate control of the channel. In addition, a fully depleted channel is generally considered to be desirable in logic transistors because this reduces or eliminates floating body effects associated with partially depleted transistors on silicon-on-insulator (SOI) substrates. However, before the present invention, it has not been recognized to use a multi-gate logic transistor design in a 1T DRAM device precisely because of the fully depletion characteristic of the multi-gate design.

The multi-gate 1T DRAM transistor of the present invention is designed to have a body region with dimensions that provide a not fully depleted region during its operation. The term not fully depleted as used herein refers to a portion of the body region that retains majority charge carriers. The gate work function sweeps out majority charge carriers in the body forming a depletion region adjacent to the gate insulator. If the dimension of the body region are such that the body region is not fully depleted then there is a neutral region with majority charge carriers remaining in the body. When a charge is injected into the body (e.g., to store a “1”), the boundary of the depletion region to neutral region shifts.

The presence of a not fully depleted body region facilitates the multi-gate transistor to transiently store charge and thereby serve as a 1T DRAM. This is in contrast to conventional multi-gate logic transistor devices where, for reasons discussed above, the entire body region is substantially fully depleted of charge carries. The present invention also recognizes that both conventional planer and multi-gate logic transistors, and multi-gate 1T DRAMs of the present invention, can be conveniently constructed concurrently in the same integrated circuit using similar processing steps.

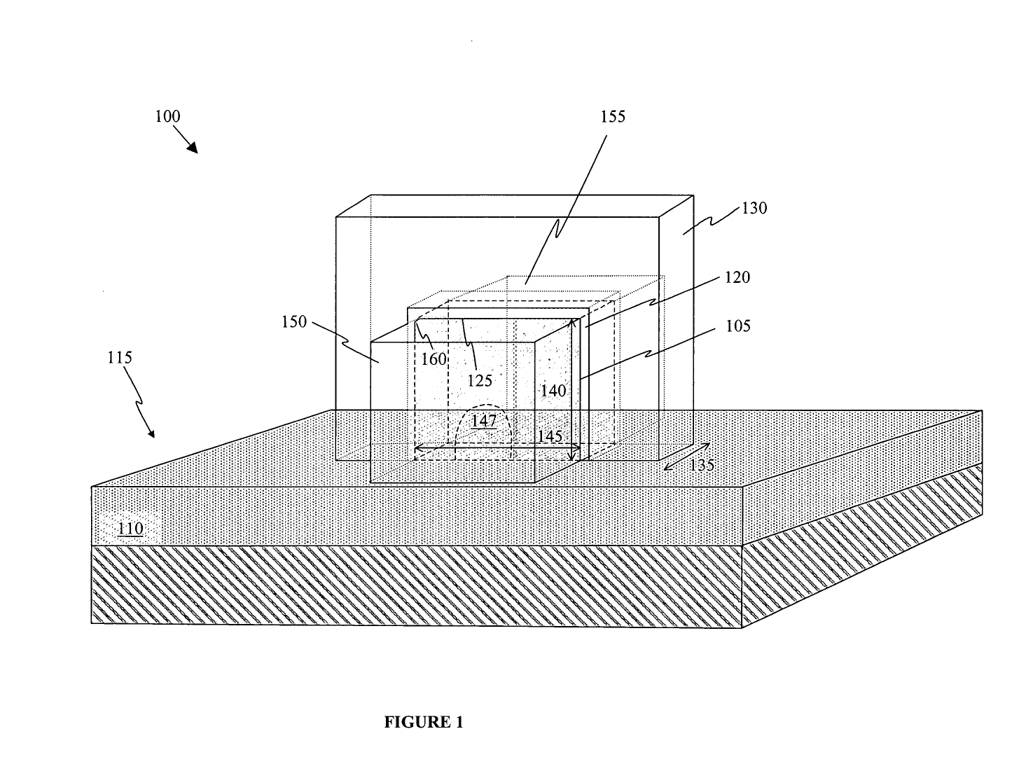

FIG. 1 illustrates a perspective view of one embodiment of a 1T DRAM device 100 of the present invention. The 1T DRAM device 100 comprises a body region 105 on an insulated layer 110 of a substrate 115. The body region 105 can be a silicon body formed from a portion of a silicon crystal layer of the a silicon-on-insulator (SOI) substrate 115 and is on a buried oxide layer 110 of the SOI, as further discussed below. Optionally, other semiconductor material such as germanium can be used.

There is an insulating layer 120 on a surface 125 of the body region 105. There is also a gate structure 130 on the insulating layer 120 that conformally surrounds a portion of the body region 105. Of course, one skilled in the art would understand that the different embodiments of the device 100 will have differing thicknesses of the insulating layer 120 and gate insulator, that in turn, cause variations in the extent to which the gate structure 130 conformally surrounds the body region 105. In contrast, the gate structure in a planer transistor does not conformally surround the channel region. The width of the body region 145 is sufficient to provide a not fully depleted region 147 in the body region 105. In one aspect, the width 145 of the body region 105 is greater than a length of the gate structure 135. In another aspect, a length 135 of the gate structure 130 is substantially equal to or less than a height 140 of the body region 105, and a width 145 of the body region 105 is greater than the gate length 135. The term width as used herein refers to a dimension between opposing surfaces of the gate structure 130 that surrounds the body region 105. In some multigate structures, such as double-gate of fin-fet structure this dimension may commonly be referred by those skilled in the art as thickness. The ends of the body region that are not surrounded by the gate structure 130 can be source and drain structures 150, 155.

The gate structure 130 can be any of a number of multi-gate structures well known to those skilled in the art. In the embodiment illustrated in FIG. 1, the gate structure 130 is a tri-gate. Other multi-gate structures, double-gates, finFETS, and other forms of tri-gates, such as pi-gates and omega-gates can also be used, however. In certain advantageous versions of the device 100, the gate structure 130 is a tri-gate or omega-gates because these structures provide superior control of the body region 105, as compared to double-gate or finFET structures for a given body width. In alternative versions, however, manufacturing considerations may favor the use of double-gate or finFET structures. Of course, one skilled in the art would understand that the not fully depleted region 147 would occupy different portions of the body region 147 depending on the particular multi-gate structure 130 being used.

The body region's dimensions are important determinants of the ability of the 1T DRAM device 100 to store memory. As noted above, at least a portion of the body region 105 is not fully depleted. When a selected voltage pulse is applied to a drain 155 of the device 100 and a gate voltage is applied to the gate structure 130. As an example, a logic state “1” could be created by applying a 2 V pulse to the drain 155 and applying a 0.5 V to the gate structure 130. A logic state of “0” could be created by applying a −2 V pulse to the drain 155 and applying a 0.5 V to the gate structure 130. Of course, one skilled in the art would understand that memory storage and retrieval could be accomplished using various voltages, depending on the design.

Though not restricting the scope of the present invention by theory, it is believed that the not fully depleted region is located in the central portions of the body region 105 remote from the gate structure 130. To facilitate the formation of a not fully depleted region, in some tri-gate structure embodiments, a ratio of the width 145 of the body region 105 to the gate length 135 is at least about 1.5:1. and more preferably between about 1.5:1 to about 3.0:1. In some double-gate or finFET structures embodiments a ratio of the width 145 of body region to the gate length 135 is at least about 1:1. In such configurations, a ratio of the height 145 of the body region 105 to the gate length 135 can range from between about 0.5:1 to about 1.5:1.

Although the 1T DRAM device 100 could be used in various sizes of devices, it is particular advantageous for sub 0.1 micron devices where dense memory is desirable. For instance, in certain devices 100, the gate length 135 is less than about 50 and more preferably less than about 35 nanometers. While in some configuration the body region 105 can comprise intrinsic material of the substrate 115, it can be advantageous to perform an additional implant to the body region to facilitate formation of a not fully depleted body region. The depletion volume in the body region 105 will depend on the gate work function and the body doping level. The higher the doping, the smaller the depletion volume and thus the less width required to maintain a not fully depleted region. However, threshold voltage and junction leakage limit doping levels. Thus an increased body width facilitates maintaining a not fully depleted region.

The dimensions of the body region 105 of the present invention are in contrast to that used in a conventional multi-gate logic transistor having a fully depleted body region. In conventional devices, if the body region is too wide, then the combined coupling of majority carriers to the gate structure 130 in all regions of the body 105 is reduced relative to the coupling to the source and drain, 150, 155 resulting in degraded transistor characteristics. Further, for a sufficiently wide body region 105, the gate 130 is unable to drive out substantially all of the majority carriers and thereby make the body region fully depleted. For instance, in a tri-gate structure in a conventional multi-gate logic transistor the body will be fully depleted and there will be good channel control by the gate when the ratio of the gate length to body width is about 1:1. In double-gate structures, the body width must be even thinner, for example, the ratio of the gate length to body width is about 1:0.66.

In certain devices 100, the body region 105 has a parallelepided shape, such as a cuboid, as illustrated in the embodiment shown in FIG. 1. However, other body shapes that are conducive for use in a multi-gate transistor can also be used. In some devices 100, body region 105 has one or more rounded corners 160. Rounded corners 160 help prevent an excessively thin insulating layer 120, thereby avoid breakdown of the insulating layer 120 at the corners 160.

Some preferred embodiments of the 1T DRAM device 100 are negative channel field effect transistors (NFET)or positive channel field effect transistors (PFET). In such configurations, it can be advantageous to dope the body region 105, for example, to obtain suitable gate threshold voltages.

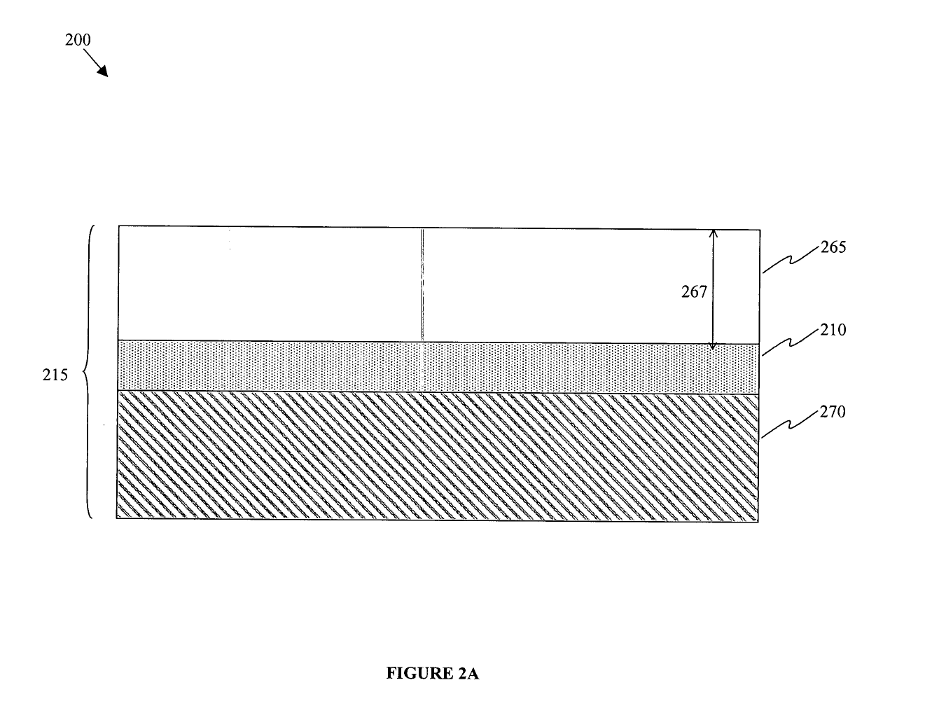

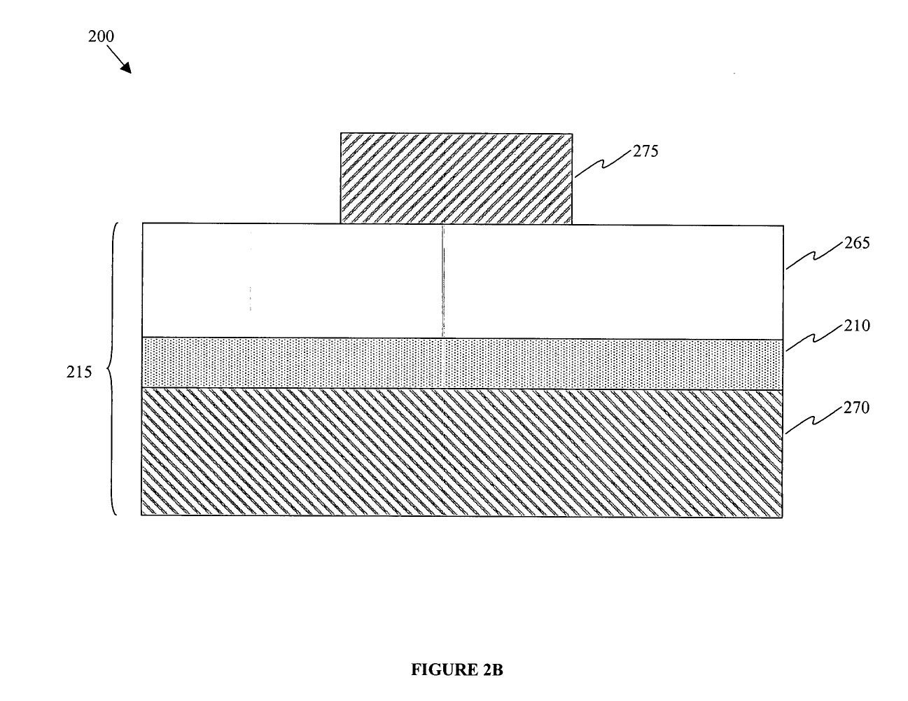

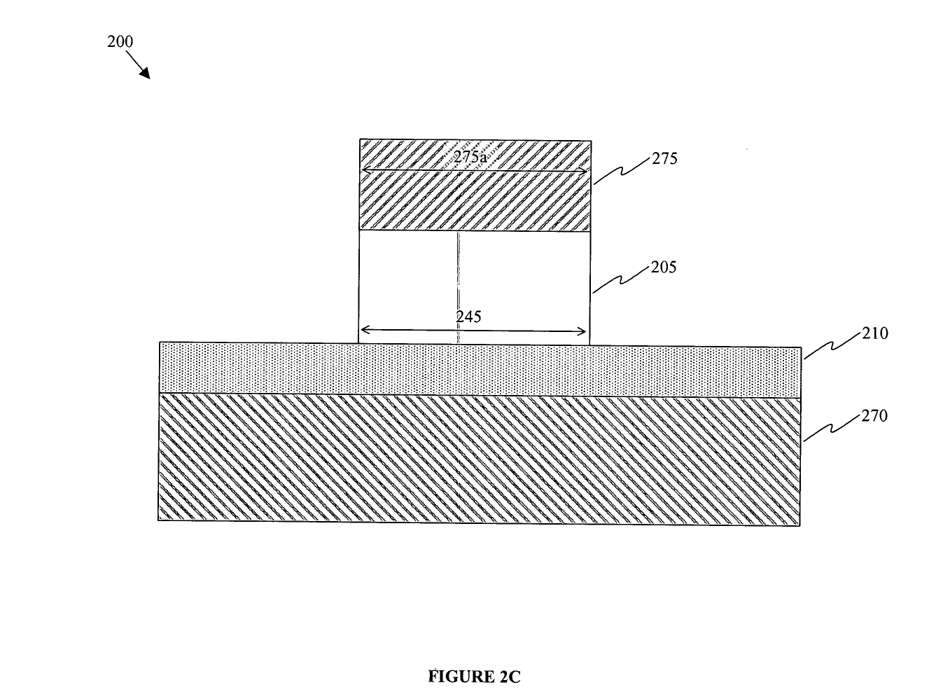

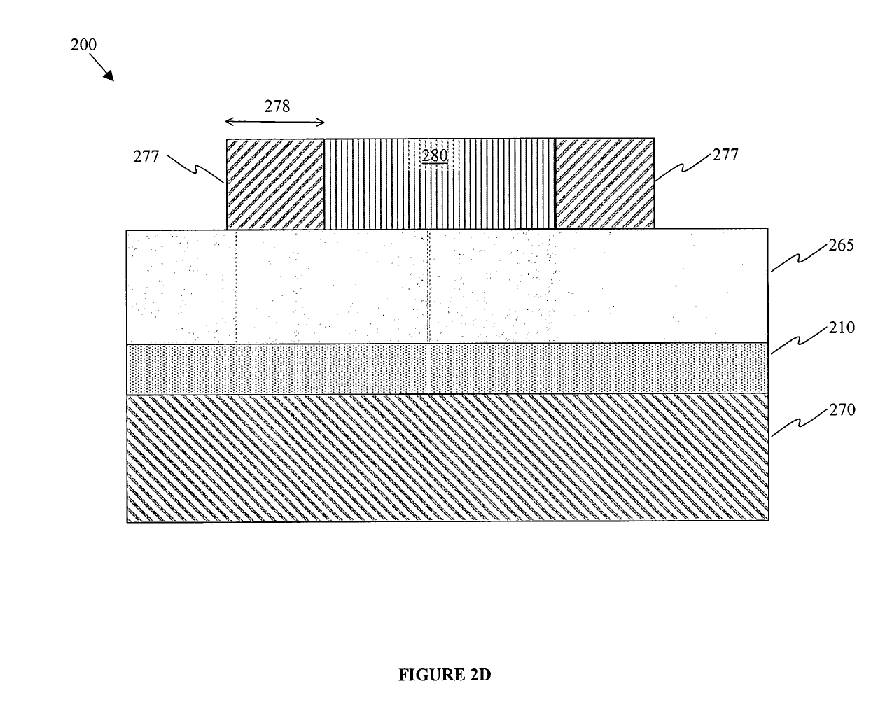

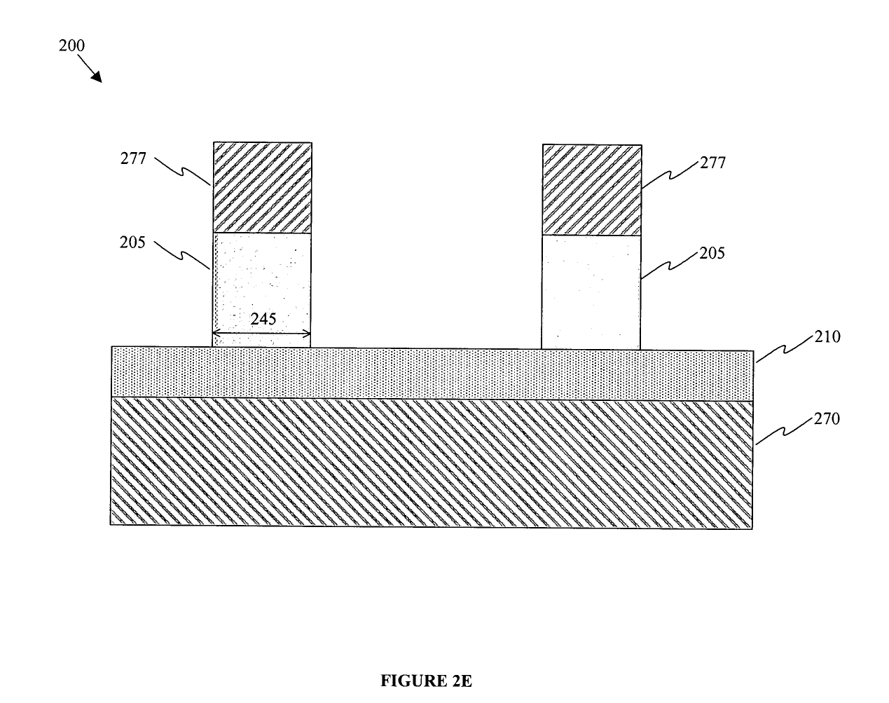

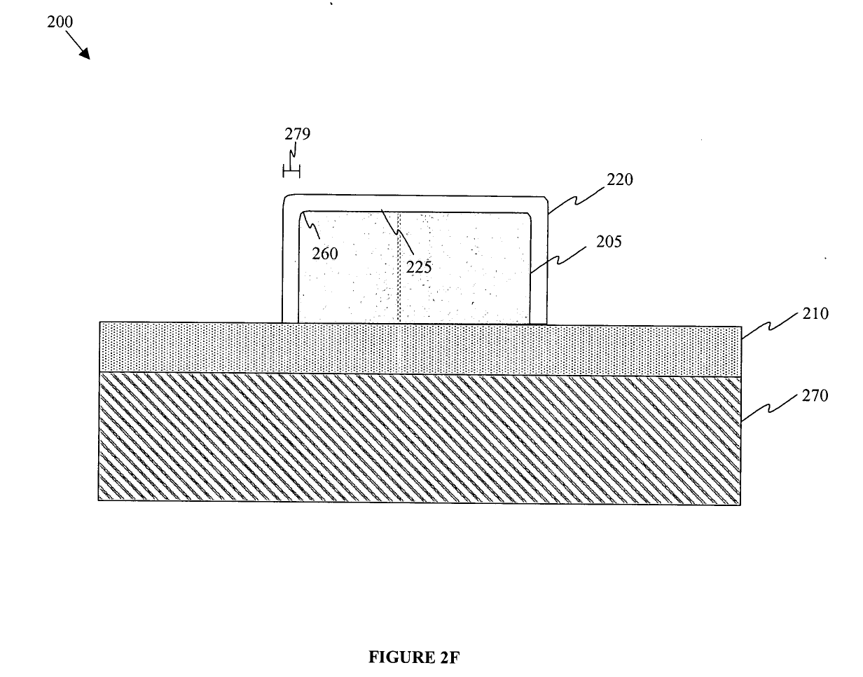

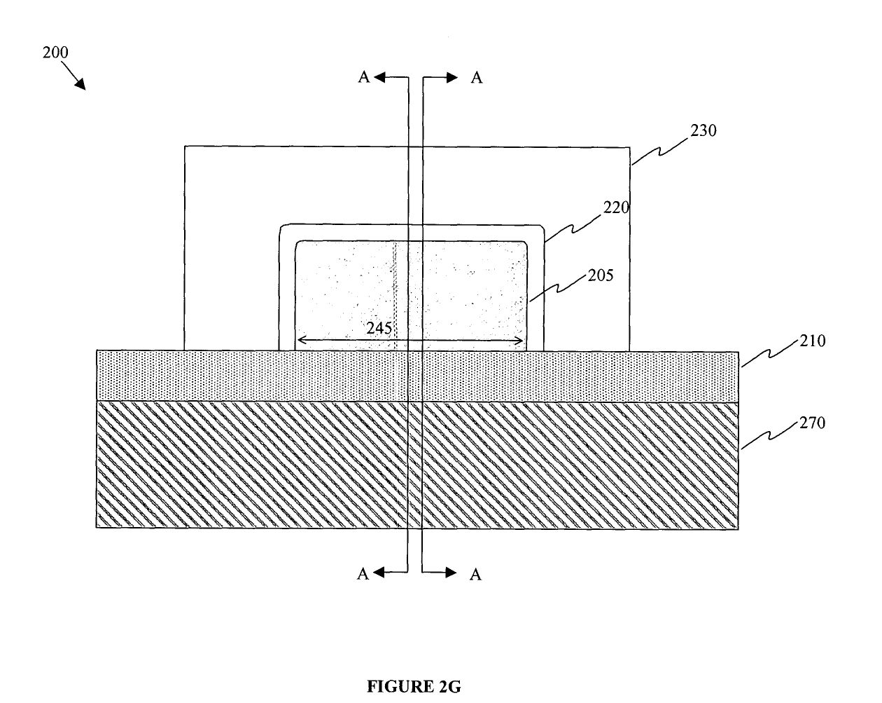

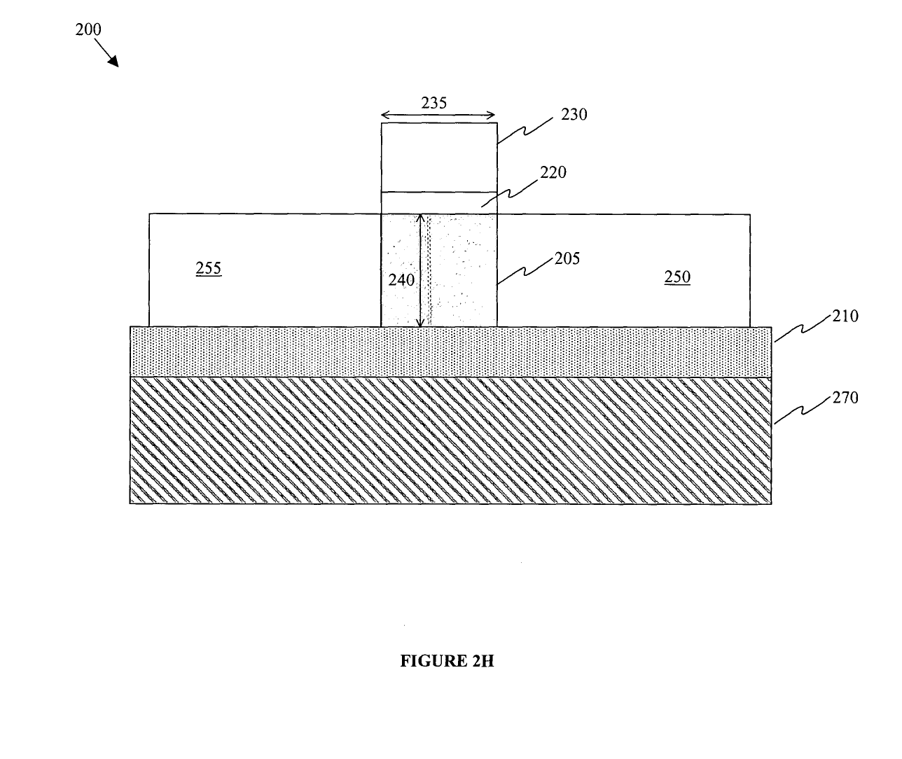

Turning to FIGS. 2A-2H, with continued reference to FIG. 1, illustrated are sectional and top views of selected steps in a method of making a 1T DRAM device 200 according to the principles of the present invention. Analogous reference numbers to that used in FIG. 1 are used to depict like structures in FIGS. 2A to 2H. Any of the embodiments of the 1T DRAM device 100, including the body region's dimensions, described for FIG. 1, can be manufactured according to the method illustrated in FIGS. 2A to 2H.

Turning now to FIG. 2A, illustrated one embodiment where the substrate 215 is a SOI substrate. Typically, the SOI substrate 215 comprises a semiconductor layer 265, such as a crystalline silicon, formed over an insulating layer 210 on a supporting bulk substrate 270. In some configurations, the silicon layer's thickness 267 is less than 50 nanometers and more preferably less than about 30 nanometers thick. In other configurations, further discussed below in the context of an integrated circuit embodiment, the silicon layer's thickness 267 is comparable to the intended logic transistor gate length.

The fabrication of SOI substrates 215 is well understood by those skilled in the art. As an example, fabrication can include ion implantation of oxygen and high temperature annealing to form the layer of silicon oxide 210, commonly referred to as buried oxide, below the crystalline silicon layer 265. An alternative SOI fabrication process involves bonding a silicon crystal layer 265 onto a bulk silicon layer 270 having a surface oxide layer 210, and then splitting off a portion of the silicon crystal layer 265, via helium implantation, to leave the silicon layer 265 with an appropriate thickness 267 on the buried oxide layer 210.

In other embodiments, however, an SOI substrate is not used. As an example, epitaxial overgrowth processes, well known to those skilled in the art, can be used. In such processes, an oxide is formed on a semiconductor surface, windows are opened down to the semiconductor and the body region is formed via epitaxal growth over the semiconductor and oxide. Alternatively, other well-known processes can be used, where a semiconductor substrate can be doped and then etch selective to the doping, so as to etch out a tunnel region of the semiconductor. The tunnel region is then filled with an oxide.

Referring now to FIGS. 2B-2C, illustrated is one method to form a body region 205, shown in FIG. 2C, from the silicon layer 265 of the SOI substrate 215 shown in FIG. 2B. FIG. 2B depicts a mask 275, preferably comprised of an energy sensitive material, such as photoresist, that has been patterned by conventional lithographic techniques, such as photolithography. As well understood by those skilled in the art, lithographic techniques are used to fabricate a wide variety of devices, such as integrated circuit devices, optical devices, or micro-electromechanical (MEMS) devices. Any of those techniques could be used in the present invention. In lithographic processes, for instance, a pattern is defined and developed in a photoresist layer to form the mask 275.

As illustrated in FIG. 2C, the mask 275 is then used to transfer the pattern into the silicon layer 265 by removing portions of the silicon layer 265 shown in FIG. 2B that are not protected by the mask 275. The silicon layer 265 is preferably removed by a conventional dry plasma anisotropic etch technique, although other procedures could be used. The remaining portion of the silicon layer protected by the mask 275 is the body region 205 depicted in FIG. 2C. In certain such embodiments, the width of the mask 275a is about the same as the width of the body region 245.

An alternative method of forming the body region 205 from the silicon layer 265 is illustrated in FIGS. 2D-2E. This method is particularly advantageous when one wishes to form closely spaced, narrow body regions 205, for example, widths 245 (FIG. 2E) of about 50 nanometers or less, and spaced apart by 50 nanometers. In other words, the pitch, the sum of the width of the body and the space between body regions, can be 100 nanometers or less. The use of sidewall masks 277 shown in FIGS. 2D and 2E advantageously allows a doubling of minimum pitch normally allowed by conventional lithographic techniques because there is a sidewall on each side of the initially patterned structure. Of course, one skilled in the art would understand that there other ways, such as patterning followed by over-etch, to facilitate the formation of sublithographic widths.

Turning to FIG. 2D, illustrated are sidewall masks 277 and a sacrificial structure 280 formed over the silicon layer 265. In certain embodiments, the sacrificial structure 280 is a gate-like structure formed by conventionally depositing a polysilicon layer, via chemical vapor deposition (CVD) for example, followed by conventional lithography to pattern and removal of portions of the polysilicon layer. The sidewall masks 277 are formed adjacent to the sacrificial structure 280. Any conventional procedure used to form gate sidewalls can be used to form the sidewall masks 277. For instance, sidewall masks 277 can be formed by depositing a silicon oxide or silicon nitride layer by CVD or physical vapor deposition (PVD), followed by an anisotropic etch to remove the silicon oxide or silicon nitride material that is remote from the sacrificial structure 280. Preferably, the sidewall masks 277 have a width 278 that is comparable to the intended gate length.

Next, the sacrificial structure 280 is removed, leaving the sidewall masks 277 as shown in FIG. 2E. Any procedure capable of selectively removing the sacrificial structure 280 but not the sidewall masks 277 may be used. As an example, a sacrificial structure 280 comprising polysilicon with oxynitride sidewall masks 277 can be removed using a etch, such as a wet etch, to selectively remove the sacrificial structure 280. Generally, it is desired to have the underlying material 210, the sidewall 277, and the sacrificial structure 280 each to be of a composition that is selectably etchable relative to the other two materials. For example, the materials may be silicon, silicon oxide, and silicon nitride. Polymers and silicon carbide are examples of other compositions that can also be used. The sidewall mask 277 is then used to transfer the pattern into the silicon layer 265, to form body regions 205 similar to that described above for the embodiment shown in FIGS. 2B2C. One technique to obtain multiple width patterns using sidewall patterning is to have two adjacent sacrificial structures sufficiently close that the sidewall merge in the reduced space. Another technique is to selectively remove initially formed sidewalls and follow with a second sidewall. Regions where the initial sidewall is left will be wider than regions where the initial sidewall is removed. This can be repeated for additional variations of width. Sidewall patterns can also be combined with lithographic patterns.

Continuing with the embodiment shown in FIG. 2C, illustrated in FIG. 2F is the partially completed device 200 after removing the mask 275. As further shown in FIG. 2F, an insulating layer 220 is formed on a surface of the body region 225. Preferably, the insulating layer 220 conforms to the surface of the body region 225. In certain advantageous configurations, the insulating layer 220 is a silicon oxide layer. The insulating layer 220 may be a thermally grown oxide or oxynitride layer, or a deposited nitride layer. Also, the insulating layer 220 may be a composite of thermally grown and deposited layers including high k materials. The thickness of the insulating layer 279 may be varied according to design consideration, but preferably, is the equivalent of between about 5 and about 20 Angstroms of silicon dioxide dielectric thickness, and more preferably, about 12 Angstroms. In certain preferred configurations, corners of body region 260 are rounded by etch or oxidation techniques.

Next, as illustrated in FIG. 2G, a gate structure 230 is formed on the insulating layer 220. Conventional processes are used to deposit and pattern the gate material to form the gate structure 230 to, in turn, conformally surround a portion of the body region 205. In some configurations, the gate structure 230 is a tri-gate, although other multi-gate structures can be formed, as noted above. In pi-gate or omega-gate variations of tri-gate, the gate 230 extends into the isolating dielectric 210. The gate structure can be comprised of any conventional gate material, such as polysilicon or metal.

FIG. 2H shows a sectional view through sectional line A-A of FIG. 2G. The ends of the silicon layer 265 that are outside of the gate structure 230 and remain after patterning can be suitably doped to form source and drain structures 250, 255. In p-channel and n-channel devices, the source and drain structures 250, 255 can be suitably implanted with boron and arsenic or phosphorus, respectively. With continuing reference to FIGS. 2G, as illustrated in FIG. 2H, a gate length 235 of the conformally surrounding gate structure 230 is substantially equal or less than a height of the body region 240, and a width of the body region 245 is greater than the gate length 235. The gate length referenced in ratios to the body dimensions is the optimized logic transistor gate length for a given technology. In some embodiments, the gate length of the transistor in the 1-T DRAM may be longer than the optimized logic transistor gate length, and the 1-T DRAM transistor gate length to body dimension ratios will change accordingly.

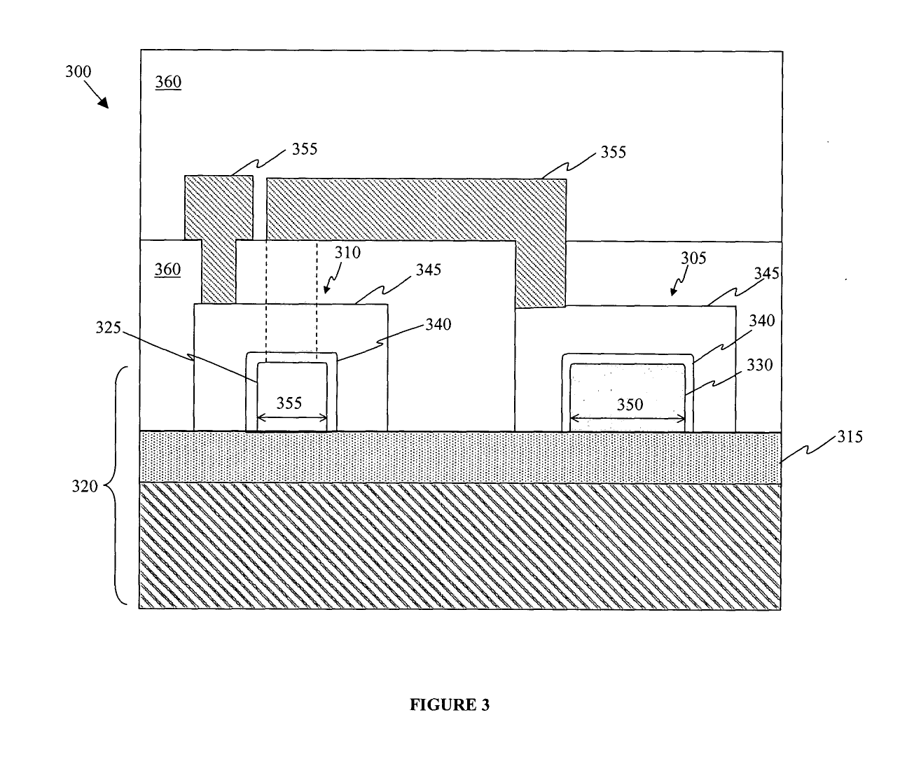

Another aspect of the present invention is an integrated circuit 300 having both a conventional multi-gate logic transistor and a 1T DRAM device as provided by the present invention. A sectional view of one embodiment of a portion of an integrated circuit 300 of the present invention is illustrated in FIG. 3. Illustrated is a partial completed integrated circuit 300, after forming a 1T DRAM device 305 and a logic transistor 310. Any of the above-described embodiments illustrated in FIG. 1 and FIGS. 2A-2H, can be used to form the 1T DRAM device 305. In some embodiments, the 1T DRAM device 305 and the logic transistor 310 are formed on the buried oxide layer 315 of an SOI substrate 320 similar to that described above.

The logic transistor device 310 can have a conventional planar-gate design. However, in applications where superior short gate length characteristics are desired, the logic transistor 310 preferably includes a multi-gate design, such as illustrated in FIG. 3. Although the multi-gate logic transistor 310 can be constructed separately, in certain embodiments it is advantageous for the transistor 310 to be constructed in conjunction with the manufacture of the 1T DRAM device 305. That is, the logic body region 325 is formed from the same silicon layer used to form the body region 330 of the 1T DRAM 305, using analogous manufacturing steps as discussed in the context of FIG. 1 and FIGS. 2A-2H.

For instance, the body region 330 and logic body region 325 can be formed concurrently by depositing and patterning a resist over the silicon layer to form masks for the body region 330 and logic body region 325, analogous to that shown in FIGS. 2B-2C or 2D-2E. This preferably is followed by an anisotropic etch performed to remove portions of the silicon layer not protected by the masks, analogous to that depicted in FIG. 2F. Likewise, substantially the same insulating layer 340 and gate structure 345 can be formed on the logic body region 325 as formed on the body region 330, analogous to that illustrated in FIG. 2G. Of course, as discussed above, a width of the body region 350 is sufficient to provide a not fully depleted region. In some embodiments, a width of the logic body region 355 is less than the body width of the 1T DRAM device 350. In still other embodiments, the width of the body region of the 1T DRAM device 350 is greater than the gate length (such as depicted in FIG. 1 or FIG. 2H) and the width of the logic body region 355 is substantially equal to the gate length. Conventional implantation procedures can be done so as to configure the logic transistor 310 into a NFET or PFET transistor, or to configure a pair of logic transistors into NFET or PFET transistors in a complementary metal oxide semiconductor (CMOS) device.

Further illustrated in FIG. 3 is a partial completed integrated circuit 300, after forming interconnects 350 to interconnect the 1T DRAM device 305 and the logic transistor 310 to form an operative integrated circuit 300. For instance, forming the interconnects 350 can include forming interconnect metals lines 355 on one of more insulating layers 360 located over the 1T DRAM device 305 and logic transistor 310, to connect the interconnects 350 with the 1T DRAM device 305 and logic transistor 310.

Although the present invention has been described in detail, one of ordinary skill in the art should understand that they can make various changes, substitutions and alterations herein without departing from the scope of the invention.

1. A one-transistor dynamic random access memory (1T DRAM) device, comprising:
a body region insulated from a substrate;
an insulating layer on a surface of said body region; and
a gate structure on said insulating layer and conformally surrounding a portion of said body region, wherein a width of said body region is sufficient to provide a not fully depleted region.

2. The 1T DRAM device as recited in claim 1, wherein said width of said body region is greater than a length of said gate structure.

3. The 1T DRAM device as recited in claim 2, wherein said gate structure is a tri-gate and a ratio of said width of said body region to said gate length is at least about 1.5:1.

4. The 1T DRAM device as recited in claim 2, wherein said gate structure is a fin-fet and a ratio of said width of said body region to said gate length is at least about 1:1.

5. The 1T DRAM device as recited in claim 1, wherein said body region is insulated from said substrate by an oxide layer.

6. The 1T DRAM device as recited in claim 1, wherein said body region is insulated from the substrate by a buried layer of a silicon-on-insulator (SOI) substrate.

7. A method of manufacturing a one-transistor dynamic random access memory (1T DRAM) device, comprising:
forming a body region insulated from a substrate;
depositing an insulating layer on a surface of said body region; and
forming a gate structure on said insulating layer and conformally surrounding a portion of said body region, wherein a width of said body region is sufficient to provide a not fully depleted region.

8. The method as recited in claim 7, wherein said width of said body region is greater than a length of said gate structure.

9. The method as recited in claim 8, wherein said gate length is less than about 35 nanometers.

10. The method as recited in claim 7, wherein said body region is formed from a silicon layer of a silicon-on-insulator (SOI) substrate.

11. The method as recited in claim 10, wherein forming said body region includes forming a mask by depositing and patterning a resist over said silicon layer and performing an anisotropic etch to remove portions of said silicon layer not protected by said mask.

12. The method as recited in claim 11, wherein said mask is a sidewall structure.

13. The method as recited in claim 7, wherein said gate structure is a tri-gate.

14. The method as recited in claim 13, wherein a ratio of said width of said body region to said gate length is at least about 1.5:1.

15. The method as recited in claim 7, wherein said gate structure is a FIN-FET.

16. The method as recited in claim 15, a ratio of said width of said body region to said gate length is at least about 1:1.

17. An integrated circuit, comprising:
a one-transistor dynamic random access memory (1T DRAM) device, including:
a body region insulated from a substrate;
an insulating layer on a surface of said body region; and
a gate structure on said insulating layer and conformally surrounding portions of said body region wherein a width of said body region is sufficient to provide a not fully depleted region;
a logic transistor located on said substrate; and
interconnects to interconnect said 1T DRAM and said logic transistor to form an operative integrated circuit.

18. The integrated circuit as recited in claim 17, wherein said logic transistor is a multigate transistor having a logic body region, a width of said logic body region being less than said body width of said 1T DRAM device.

19. The integrated circuit as recited in claim 17, wherein said logic transistor further comprises:
a logic body region; and
an insulating layer on said surface of said logic body region, wherein said gate structure is on said insulating layer and said gate structure conformally surrounds portions of said logic body region and said gate length is substantially equal to a height and to a width of said logic body region.

20. The integrated circuit as recited in claim 17, wherein a logic body region of said logic transistor is fully depleted.
